(19) United States
(12) Patent Application Publication
(10) Pub. No.: US 2024/0155835 A1
(43) Pub. Date: May 9, 2024

(54) DYNAMIC RANDOM ACCESS MEMORY AND MANUFACTURING METHOD THEREOF

(71) Applicant: Winbond Electronics Corp., Taichung City (TW)

(72) Inventor: Hao-Chuan Chang, Taichung City (TW)

(73) Assignee: Winbond Electronics Corp., Taichung City (TW)

(21) Appl. No.: 18/473,317

(22) Filed: Sep. 25, 2023

(30) Foreign Application Priority Data
Nov. 9, 2022 (TW) 111142755

(51) Int. Cl. H10B 12/00

(52) U.S. Cl. CPC H10B 12/485; H10B 12/033; H10B 12/315; H10B 12/482

(57) ABSTRACT

A DRAM including a substrate, a plurality of bit line structures, and a contact is provided. The substrate has an active area. The bit line structures are arranged on the substrate, and each bit line structure at least includes a conductive structure, an insulating cover layer and a spacer. The insulating cover layer is arranged on the conductive structure. The spacer is arranged on the side wall of the conductive structure and the side wall of the insulating cover layer. The conductive structure is configured to be electrically connected to the active area. The contact is located between the bit line structures, and at least a part of the contact extends below the spacer of one of the bit line structures.

### CROSS-REFERENCE TO RELATED APPLICATION

This application claims the priority benefit of Taiwan application serial no. 111142755, filed on Nov. 9, 2022. The entirety of the above-mentioned patent application is hereby incorporated by reference herein and made a part of this specification.

### BACKGROUND

### Field of the Disclosure

The present disclosure relates to a memory device and a manufacturing method thereof, and in particular to a dynamic random access memory (DRAM) and a manufacturing method thereof.

### Description of Related Art

With the progress of technologies, various kinds of electronic products are designed to be light, thin and small. However, as the trend develops, the critical dimension of the DRAM is also gradually reduced, which leads to an increase in the contact resistance between the contact and the active area in the DRAM and causes reduction of reliability. Therefore, how to reduce the contact resistance between the contact and the active area and improve the reliability of DRAM will be a very important issue.

### SUMMARY OF THE DISCLOSURE

The present disclosure provides a dynamic random access memory (DRAM) and a manufacturing method thereof, which are able to reduce the contact resistance between the contact of a capacitor and the active area, as well as improve reliability.

A DRAM of the disclosure includes a substrate, a plurality of isolation structures, a plurality of bit line structures, and a contact. The substrate has an active area. The plurality of isolation structures are formed in the substrate to separate the active area. The bit line structures are arranged on the substrate, and each bit line structure at least includes a conductive structure, an insulating cover layer and a spacer. The insulating cover layer is arranged on the conductive structure. The spacer is arranged on the side wall of the conductive structure and the side wall of the insulating cover layer. The conductive structure is configured to be electrically connected to the active area. The contact is located between the bit line structures, and at least a part of the contact extends below the spacer of one of the plurality of bit line structures.

The manufacturing method of the DRAM of the present disclosure at least includes the following steps. A substrate having an active area is provided. A plurality of bit line structures are formed on the substrate. Each bit line structure at least includes a conductive structure, an insulating cover layer and a spacer. The insulating cover layer is disposed on the conductive structure, the spacer is disposed on the side wall of the conductive structure and the side wall of the insulating cover layer, and the conductive structure is configured to be electrically connected with the active area. A groove is formed between the adjacent bit line structures, and the groove exposes part of the active area. An oxidation process is performed so that the exposed active area is formed into an oxide layer. The oxide layer is removed so that the groove extends below the spacer to form a contact opening. A contact is formed in the contact opening.

Based on the above, the present disclosure is able to increase the area of the active area exposed by the contact opening by locally oxidizing the active area exposed by the contact opening and removing the formed oxide layer. In this way, the contact area between the contact and the active area formed subsequently in the contact opening may be increased, thereby reducing the contact resistance between the contact and the active area, and improving the reliability of DRAM.

### BRIEF DESCRIPTION OF THE DRAWINGS

FIG. 1A to FIG. 1F are partial cross-sectional views of a manufacturing process of a dynamic random access memory (DRAM) manufacturing method according to an embodiment of the present disclosure.

### DESCRIPTION OF EMBODIMENTS

The present disclosure will be described more comprehensively with reference to the drawings of the present embodiment. However, the present disclosure can also be embodied in various forms without being limited to the embodiments described herein. The thicknesses of layers and regions in the drawings may be exaggerated for clarity. The same or similar symbols indicate the same or similar elements, and the following paragraphs will not repeat the same details.

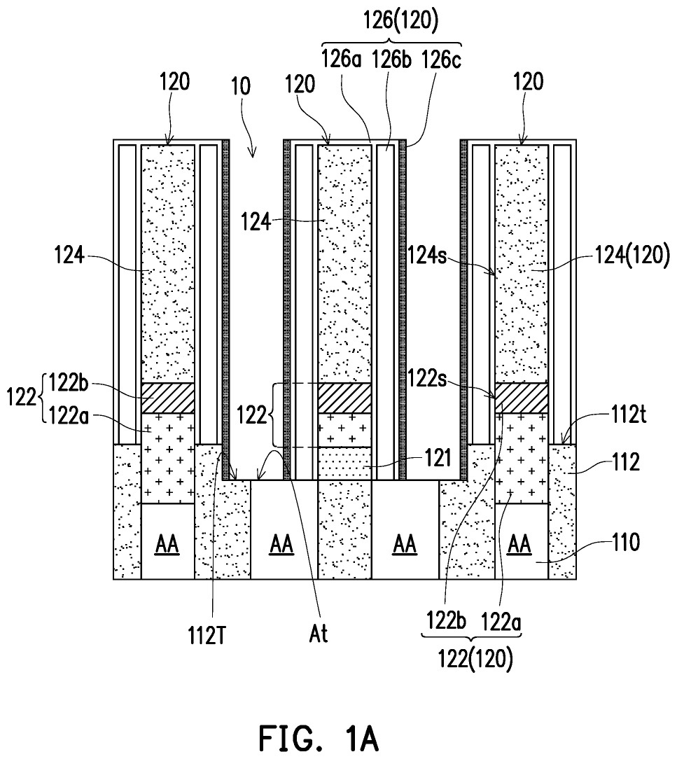

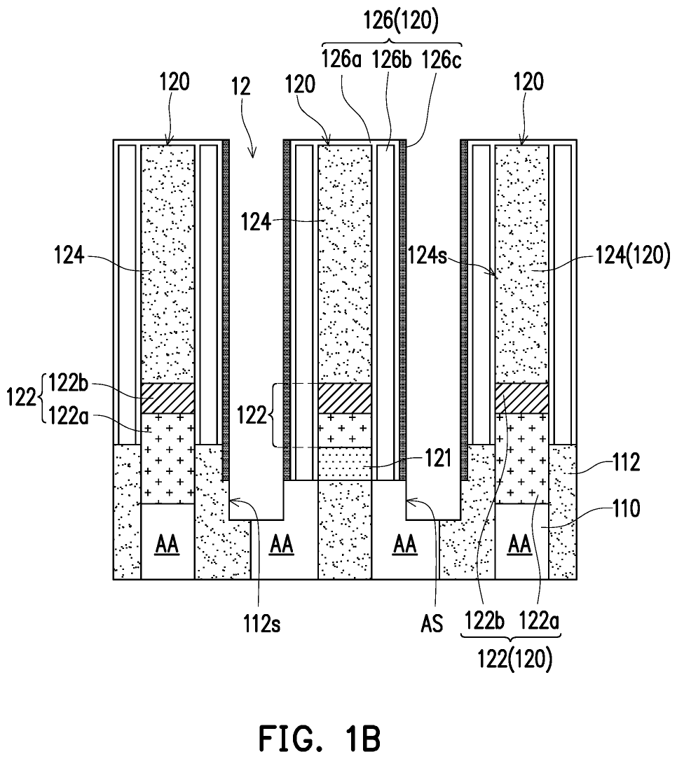

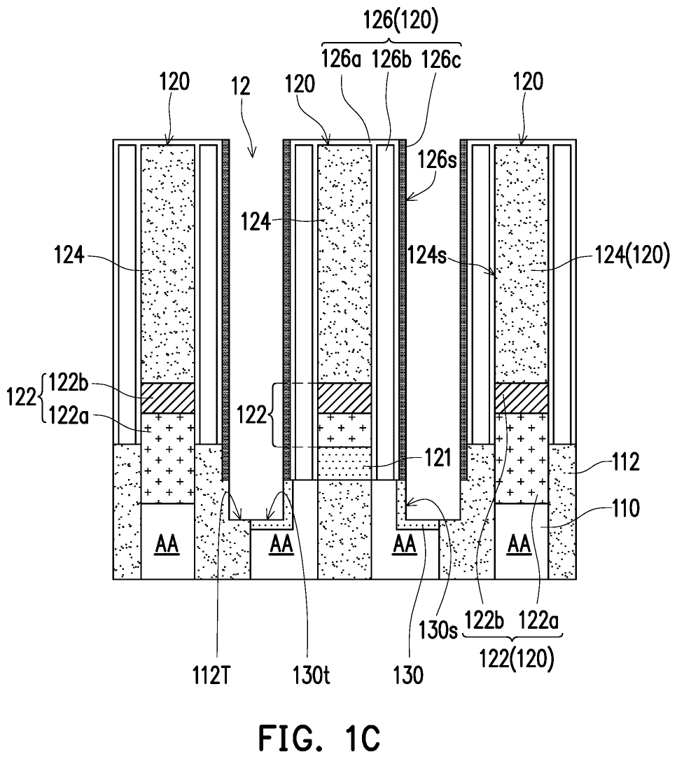

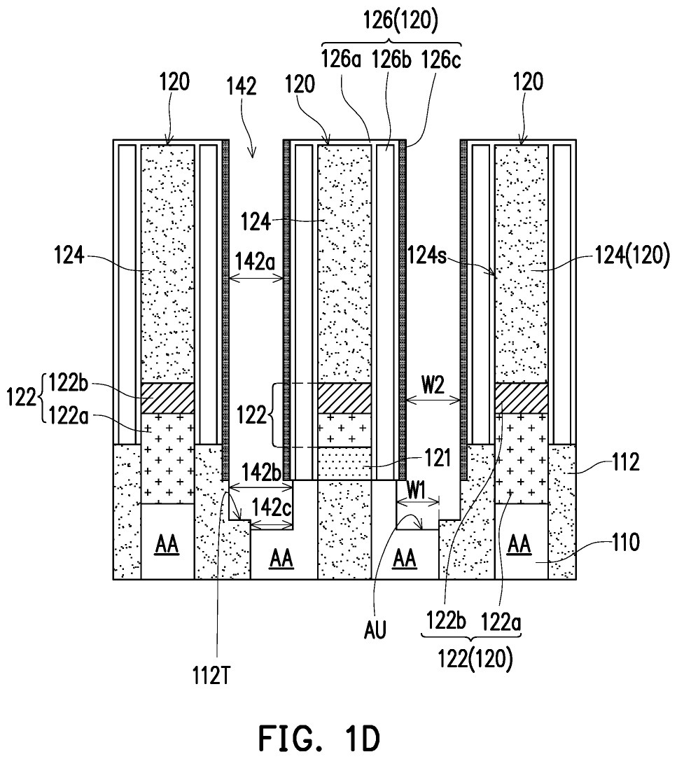

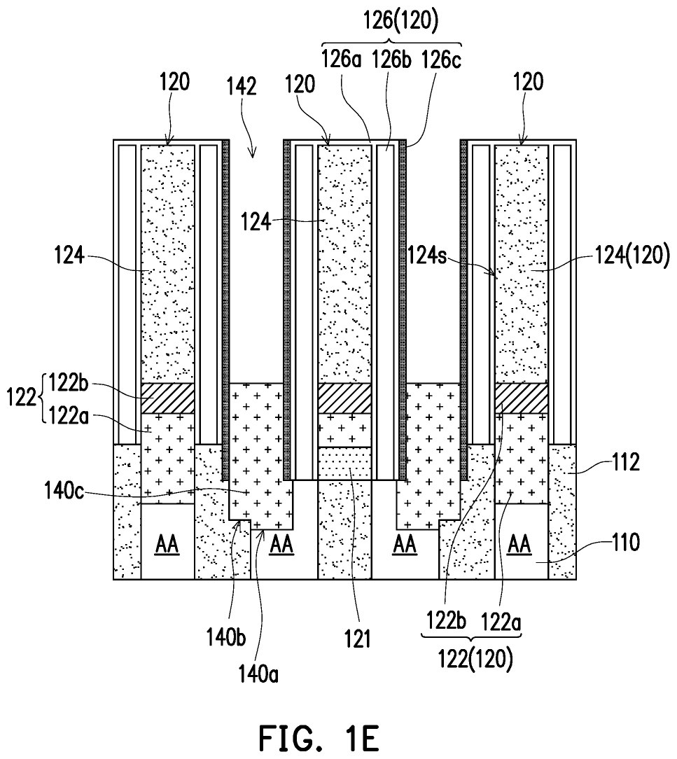

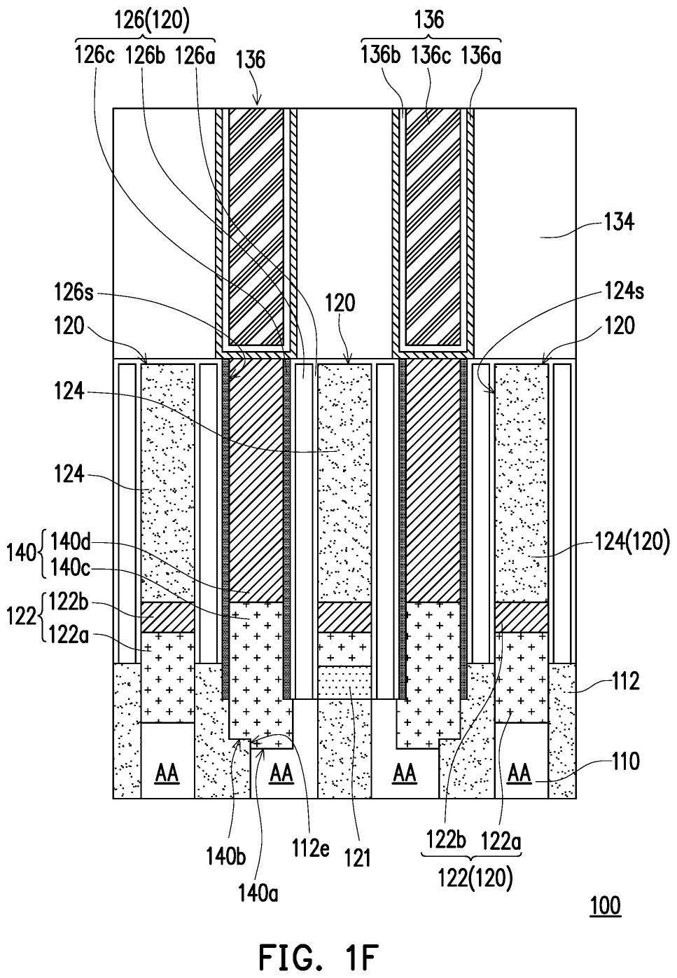

The present embodiment provides a method for manufacturing a dynamic random access memory (DRAM). Referring to FIG. 1A, a substrate 110 is provided. In this embodiment, a plurality of isolation structures 112 are disposed in the substrate 110, and the isolation structures 112 may be configured to separate a plurality of active areas AA formed in the substrate 110. For example, the isolation structures 112 may be a shallow trench isolation (STI) structure.

In some embodiments, the substrate 110 may be a semiconductor substrate or a semiconductor on insulator (SOI) substrate. The semiconductor material in the semiconductor substrate or the SOI substrate may include elemental semiconductors, alloy semiconductors, or compound semiconductors. For example, elemental semiconductors may include silicon (Si) or germanium (Ge). Alloy semiconductors may include silicon germanium (SiGe), silicon carbide (SiC), silicon germanium carbide (SiGeC), and the like. The compound semiconductor may include a group III-V semiconductor material or a group II-VI semiconductor material, but the present disclosure is not limited thereto. In some embodiments, the substrate 110 may be doped to a first conductivity type or a second conductivity type complementary to the first conductivity type. For example, the first conductivity type may be N type, and the second conductivity type may be P type.

In some embodiments, the material of the isolation structure 112 in the substrate 110 is an insulating material. For example, the material of the isolation structure 112 may respectively include silicon oxide, silicon nitride, silicon oxynitride, and the like or a combination thereof, but the disclosure is not limited thereto. In addition, the method of forming the isolation structure 112 is, for example, forming a plurality of trenches (not shown) in the substrate 110 and then filling the insulating material. Next, a removal process is performed to remove the insulating material from the substrate 110 to form the isolation structure 112 with a flat top surface 112t, and the removal process may be a chemical mechanical polishing process (CMP) or an etch-back process, but the present disclosure is not limited thereto.

Next, a plurality of bit line structures 120 may be formed on the substrate 110, and each bit line structure 120 may at least include a conductive structure 122, an insulating cover layer 124, and a spacer 126. Further, the insulating cover layer 124 may be disposed on the conductive structure 122, the spacer 126 may be disposed on the side wall 122s of the conductive structure 122 and the side wall 124s of the insulating cover layer 124, and the conductive structure 122 may be configured to be electrically connected to the active area AA. On the other hand, one of the plurality of bit line structures 120 may further include an insulating layer 121, and the insulating layer 121 is located between the conductive structure 122 and the substrate 110, but the disclosure is not limited thereto.

The material of the conductive structure 122 may include doped or undoped polysilicon, metal materials (such as tungsten), for example, include a bit line contact structure 122a and a bit line 122b, and the material of the bit line contact structure 122a may be different from that of the bit line 122b. In some embodiments, the material of the bit line contact structure 122a is doped polysilicon, and the material of the bit line 122b is tungsten, but the disclosure is not limited thereto.

Moreover, the material of the insulating layer 121, the material of the insulating cover layer 124, and the material of the spacer for forming the spacer 126 respectively include, for example, silicon oxide, silicon nitride, silicon oxynitride, and the like or a combination thereof, but the present disclosure is not limited thereto.

As shown in FIG. 1A, the spacer 126 may be a three-layer structure (spacer 126a, spacer 126b, and spacer 126c), but the present disclosure is not limited thereto, and the number of layers of the spacer 126 may be adjusted according to the actual design. For example, the spacer 126 may be a structure with a single layer, double layers or more than three layers.

In some embodiments, the method of forming the above-mentioned layers is, for example, performing deposition on the substrate 110 through chemical vapor deposition (CVD), and then forming the layers through a suitable patterning process, but the present disclosure is not limited thereto.

In this embodiment, a groove 10 is formed between adjacent bit line structures 120, and the groove 10 may expose part of the active area AA, such as exposing the top surface At of the active area AA below the spacer 126, and the downward direction is, for example, a direction facing the substrate 110. On the other hand, the groove 10 may also expose part of the isolation structure 112, such as exposing the surface 112T of the isolation structure 112 outside the spacer 126, so that the surface 112T is lower than the top surface 112t, but the disclosure is not limited thereto.

In detail, the spacer material used to form the spacer 126c may be formed on the entire substrate 110 first, and then the horizontal part of the spacer material is removed by using an etching process (such as a wet etching process) to form the spacer 126c and the groove 10 that expose parts of the active area AA and the isolation structure 112, but the disclosure is not limited thereto.

Please refer to FIG. 1B, then, the depth of the groove 10 may be increased by an etch-back process to form a groove 12 whose depth is greater than that of the groove 10, but the present disclosure is not limited thereto. Furthermore, the groove 12 may further expose more parts of the active area AA, such as exposing the side wall AS of the active area AA below the spacer 126. On the other hand, the groove 12 may further expose more parts of the isolation structure 112, such as exposing the side wall 112s of the isolation structure 112 below the spacer 126, but the disclosure is not limited thereto.

Referring to FIG. 1C, an oxidation process is performed to form an oxide layer 130 in the active area AA exposed by the groove 12. In some embodiments, the oxide layer 130 directly performs oxidation on the exposed active area AA. For example, the material of the active area AA is silicon, and the oxide layer 130 made of silicon oxide may be formed after the active area AA is directly oxidized, but the present disclosure is not limited thereto. Furthermore, the oxide layer 130 may be formed by an in-situ steam generation method (ISSG), so the thickness of the oxide layer 130 may be controlled more easily, and the structure of other parts will not be affected later, but the present disclosure is not limited thereto.

In an embodiment, the orthographic projection of the spacer 126 on the substrate 110 and the orthographic projection of the oxide layer 130 on the substrate 110 at least partially overlap each other. In other words, part of the oxide layer 130 may be formed below the spacer 126, but the present disclosure is not limited thereto.

In some embodiments, the side wall 130s of the oxide layer 130 may be substantially aligned with the side wall 126s of the spacer 126, and the surface 130t of the oxide layer 130 may be substantially aligned with the surface 112T of the isolation structure 112, but the present disclosure is not limited thereto.

Referring to FIG. 1D, then, the oxide layer 130 is removed, so that the groove 12 extends below the spacer 126, thereby forming the contact opening 142, and thus increasing the area of the active area AA exposed by the contact opening 142. Furthermore, since only the oxide layer 130 is removed without removing the isolation structure 112 at the bottom of the contact opening 142, the bottom surface of the contact opening 142 has a cross section in a step shape, but the disclosure is not limited thereto.

In some embodiments, a part of the contact opening 142 is located below the spacer 126c, so that the outer side wall of the active area AA located below the spacer 126 is retracted compared to the outer side wall of the spacer 126c. That is, the width W1 of the active area AA located below the spacer 126 is smaller than the width W2 of the spacer 126. Further, the width W1 may be the minimum width of the active area AA, and the width W2 may be the maximum width of the spacer 126. On the other hand, the contact opening 142 may expose part of the isolation structure 112, and the surface 112T of the isolation structure 112 at the bottom of the contact opening 142 is higher than the surface AU of the active area AA, so that the bottom surface of the contact opening 142 is in a step shape, but the present disclosure is not limited thereto.

In some embodiments, the contact opening 142 has a width 142a, a width 142b, and a width 142c, and the width 142a, the width 142b, and the width 142c are different from each other. The width 142c is closest to the substrate 110, for example, the width 142a is farthest from the substrate 110, and the width 142b is located between the width 142a and the width 142c. The width 142b may be greater than the width 142a and the width 142c, and the width 142a may be greater than the width 142c, but the disclosure is not limited thereto.

In an embodiment, the bottom of the contact opening 142 is located below the spacer 126 of the bit line structure 120 having the insulating layer 121, that is, the contact opening 142 extends below one of the plurality of bit line structures 120, but the present disclosure is not limited thereto.

Please refer to FIG. 1E and FIG. 1F, and then, a contact 140 is formed in the contact opening 142. In some embodiments, the contact 140 has a first portion 140c and a second portion 140d on the first portion 140c. The first portion 140c of the contact 140 has a non-aligned bottom surface 140b and a bottom surface 140a. In other words, the bottom surface of the contact 140 has a cross section in a step shape, but the disclosure is not limited thereto. The bottom surface 140b of the contact 140 is higher than the bottom surface 140a, the bottom surface 140b is in contact with the isolation structure 112, and the bottom surface 140a is in contact with the active area AA. Here, the material of the first portion 140c of the contact 140 may include doped polysilicon.

The material of the second portion 140d of the contact 140 may be different from that of the first portion 140c, for example, the material of the second portion 140d may be tungsten. It should be noted that the present disclosure does not limit the conductive material to be filled with different conductive materials in batches, and in other embodiments that are not shown, a single conductive material may also be filled in the contact opening 142.

After the above process, the manufacture of the DRAM 100 of this embodiment may be substantially completed. The DRAM 100 includes a substrate 110, a plurality of bit line structures 120, and a contact 140. The substrate 110 has an active area AA. The plurality of bit line structures 120 are disposed on the substrate 110, and each bit line structure 120 at least includes a conductive structure 122, an insulating cover layer 124, and a spacer 126. The insulating cover layer 124 is disposed on the conductive structure 122. The spacer 126 is disposed on the side wall 122s of the conductive structure 122 and the side wall 124s of the insulating cover layer 124. The conductive structure 122 is configured to be electrically connected to the active area AA. The contact 140 is located between the plurality of bit line structures 120, and at least a portion of the contact 140 extends below the spacer 126 of one of the plurality of bit line structures 120. Accordingly, in this embodiment, part of the active area AA is formed into the oxide layer 130 by performing an oxidation process on the active area AA exposed by the contact opening 142, and then, the oxide layer 130 is removed to form the contact opening 142 extending below the spacer 126 of the bit line structure 120. In this manner, at least a portion of the contact 140 formed in the contact opening 142 may extend below the spacer 126 of the bit line structure 120, thus effectively improving the contact area between the contact 140 and the active area AA and reducing the contact resistance between the contact 140 and the active area AA, as well as improving the reliability of the DRAM. In addition, by performing the oxidation process, the depth and position of the contact opening may be controlled more precisely, but the disclosure is not limited thereto.

In some embodiments, the contact 140 may be embedded in the substrate 110, for example, the contact 140 may be embedded in the active area AA, and the contact 140 is directly in contact with the side wall 126s of the spacer 126 and at least a portion of the below of the spacer 126, but the present disclosure is not limited thereto.

In some embodiments, the edge 112e of the isolation structure 112 is located within the contact 140, in other words, the isolation structure 112 is in direct contact with the contact 140. In some embodiments, at least a portion of the contact 140 extends below the spacer 126 of one of the plurality of bit line structures 120 having the insulating layer 121. In some embodiments, the orthographic projection of the contact 140 on the substrate 110 and the orthographic projection of the spacer 126 on the substrate 110 at least partially overlap each other.

In some embodiments, a portion of the bit line structure 120 electrically connected to the active area AA may be regarded as a source, and the contact 140 may be electrically connected to the drain. On the other hand, the DRAM 100 may further have a gate (not shown) between the source and the drain, and the gate may be a buried gate, but the disclosure is not limited thereto. In addition, a capacitor 136 may be further disposed above the contact 140, so the contact 140 may be a capacitor contact. In detail, an interlayer dielectric layer 134 and a capacitor 136 located in the interlayer dielectric layer 134 may be formed. The capacitor 136 includes a lower electrode 136a, a capacitor dielectric layer 136b, and an upper electrode 136c. The structure of the capacitor 136 only serves as an example, and the disclosure is not limited thereto. The lower electrode 136a of the capacitor 136 is connected to the contact 140, so that the capacitor 136 may be electrically connected to the active area AA through the contact 140. Since the process of forming the interlayer dielectric layer 134 and the capacitor 136 is known to those skilled in the art, related description is omitted here.

In summary, the present disclosure forms an oxide layer by partially oxidizing the active area exposed by the contact opening, and then removes the aforementioned oxide layer to form a contact opening extending below the spacer of the bit line structure. As such, at least a portion of the contact formed in the contact opening subsequently may extend below the spacer of the bit line structure. In this way, the contact area between the contact and the active area may be effectively increased, the contact resistance between the contact and the active area may be reduced, and the reliability of the DRAM may be improved. The invention is suitable for producing miniaturized DRAMs to increase the total number of dies on the wafer. Therefore, the present invention can reduce the production cost and energy consumption of manufacturing a single IC, and reduce the production energy consumption of subsequent packaging, thereby reducing carbon emissions in the production process of DRAMs. Furthermore, since the reliability of the DRAM of the present invention is improved, the present invention provides a green semiconductor technology.

Accordingly, the present disclosure may be used on automotive electronics, such as Advanced Driver Assistance Systems (ADAS), Instrument Clusters, Infotainment. The present disclosure may be used on Industrial applications, such as aerospace, medical, safety equipment, health & fitness, industrial controls, instrumentation, security, transportation, telecommunications, PoS machines, human machine interface, programmable logic controller, smart meter, and industrial networking. The present disclosure may be used on communication and networking devices such as STB, switches, routers, passive optical networks, xDSL, wireless access point, cable modem, power line communications M2M, mobile phones, base stations, DECT phones, and many other new communication products. The present disclosure may be used on desktops, notebooks, servers, gaming notebooks, ultrabooks, tablets, convertibles, HDD, and SSD. The present disclosure may be used on space constrained applications including Wearable, MP3 players, smart watches, games, digital radio, toys, cameras, digital photo album, GPS, Bluetooth and WiFi modules. The present disclosure may be used on television, display and home electronics.

Although the present disclosure has been disclosed as above with embodiments, it is not intended to limit the present disclosure. Those with ordinary knowledge in the technical field may make some modifications and changes without departing from the spirit and scope of the present disclosure. Therefore, the scope to be protected by the present disclosure should be defined by the scope of the appended claims.

What is claimed is:

1. A dynamic random access memory (DRAM), comprising:
a substrate, which has an active area;
a plurality of isolation structures, which are formed in the substrate to separate the active area;
a plurality of bit line structures, which are disposed on the substrate, and each of the bit line structures at least comprising a conductive structure, an insulating cover layer and a spacer, wherein the insulating cover layer is disposed on the conductive structure, the spacer is disposed on a side wall of the conductive structure and a side wall of the insulating cover layer, the conductive structure is configured to be electrically connected to the active area; and
a contact, which is located between the bit line structures, and at least a portion of the contact extending below the spacer of one of the bit line structures.

2. The DRAM according to claim 1, wherein the contact is embedded in the substrate.

3. The DRAM according to claim 1, wherein the contact is directly in contact with a side wall of the spacer and at least a portion of the below of the spacer.

4. The DRAM according to claim 1, wherein the contact has a first bottom surface and a second bottom surface, the first bottom surface is in contact with the active area, the second bottom surface is in contact with the isolation structure, and the second bottom surface is higher than the first bottom surface.

5. The DRAM according to claim 1, wherein the contact comprises a first portion and a second portion, the first portion is formed on the second portion, and a material of the first portion is different from that of the second portion.

6. The DRAM according to claim 1, wherein an edge of one of the isolation structures is located within the contact.

7. The DRAM according to claim 1, wherein another one of the bit line structures further comprises an insulating layer, which is located between the conductive structure and the substrate, and at least a portion of the contact extends below the spacer of the other one of the bit line structures.

8. The DRAM according to claim 1, further comprising:
a capacitor, disposed above the contact.

9. A method for manufacturing a dynamic random access memory (DRAM), comprising:
providing a substrate having an active area;
forming a plurality of bit line structures on the substrate, wherein each of the bit line structures at least comprises a conductive structure, an insulating cover layer and a spacer, the insulating cover layer is disposed on the conductive structure, the spacer is disposed on a side wall of the conductive structure and a side wall of the insulating cover layer, and the conductive structure is configured to be electrically connected with the active area, wherein a groove is formed between the adjacent bit line structures, and the groove exposes a portion of the active area;
performing an oxidation process so that the exposed active area is formed into an oxide layer;
removing the oxide layer so that the groove extends below the spacer to form a contact opening; and
forming a contact in the contact opening.

10. The method for manufacturing the DRAM according to claim 9, wherein the step of forming the groove further comprises performing an etch-back process to increase a depth of the groove.

11. The method for manufacturing the DRAM according to claim 9, wherein the below of the spacer has an isolation structure, and the contact opening exposes a portion of the isolation structure.

12. The method for manufacturing the DRAM according to claim 9, wherein a bottom surface of the contact opening has a cross section in a step shape.

13. The method for manufacturing the DRAM according to claim 9, wherein the contact opening has a first width, a second width, and a third width, the first width is farthest from the substrate, the third width is the closest to the substrate, and the second width is located between the first width and the third width, and the second width is greater than the first width and the third width.

14. The method for manufacturing the DRAM according to claim 9, wherein one of the bit line structures further comprises an insulating layer, the insulating layer is located between the conductive structure and the substrate, and the contact opening extends below the one of the bit line structures.

15. The method for manufacturing the DRAM according to claim 9, wherein the contact is embedded in the substrate.

16. The method for manufacturing the DRAM according to claim 9, wherein the contact is directly in contact with a side wall of the spacer and at least a portion of the below of the spacer.

17. The method for manufacturing the DRAM according to claim 9, wherein the contact has a first bottom surface and a second bottom surface, the first bottom surface is in contact with the active area, the second bottom surface is in contact with the isolation structure, and the second bottom surface is higher than the first bottom surface.

18. The method for manufacturing the DRAM according to claim 9, wherein the contact comprises a first portion and a second portion, the first portion is formed on the second portion, and a material of the first portion is different from that of the second portion.

19. The method for manufacturing the DRAM according to claim 11, wherein an edge of the isolation structure is located within the contact.

20. The method for manufacturing the DRAM according to claim 11, further comprising:
forming a capacitor disposed above the contact.
